(19) United States
(12) Patent Application Publication
(10) Pub. No.: US 2024/0055952 A1
(43) Pub. Date: Feb. 15, 2024

(54) STATOR, METHOD FOR SIMULATION, COMPUTER PROGRAM PRODUCT

(71) Applicant: Flender GmbH, 46395 Bocholt (DE)

(72) Inventor: Günther Winkler, Freinberg (AT)

(73) Assignee: Flender GmbH, 46395 Bocholt (DE)

(21) Appl. No.: 18/270,820

(22) PCT Filed: Dec. 3, 2021
(86) PCT No.: PCT/EP2021/084120

§ 371 Date: Jul. 3, 2023

(30) Foreign Application Priority Data
Jan. 5, 2021 (EP) 21150248.9

(51) Int. Cl. H02K 9/19; H02K 1/20; G06F 30/20

(52) U.S. Cl. CPC H02K 9/19; H02K 1/20; G06F 30/20

(57) ABSTRACT

A stator of an electromechanical transducer includes a winding system and a cooling system designed for through-flow of a cooling medium and including a nozzle through which the cooling medium flows during operation, such that the cooling medium flows out as an accelerated jet downstream of the nozzle. The nozzle is oriented such that part of the winding system is struck by the accelerated jet from the nozzle. A core includes cutouts for at least partial arrangement of winding sections of the winding system. The core includes a magnetically permeable body designed to include at least a first body and a second body which are arranged axially next to one another, with the first body being arranged in spaced-apart relationship from the second body to define an axial gap there between, with the cooling medium being combined in the axial gap from various flow paths guided in a parallel fashion.

The invention relates to a stator of an electromechanical transducer, in particular of a dynamo-electric machine, configured for interaction with a rotor, comprising
a cooling system,
a winding system,
a core, comprising at least one magnetically permeable body,
   wherein the stator extends along a longitudinal axis, wherein the core has cutouts, in which winding sections of the winding system are at least partly arranged, and wherein the cooling system is designed for through-flow by means of a cooling medium.

Electromechanical transducers are electric motors or generators, in particular dynamo-electric machines.

The stator of an electromechanical transducer, in particular the winding system, has to be cooled on account of the losses, for example iron losses (core), conductor losses, etc. For efficient heat dissipation, air cooling is normally no longer sufficient, and so liquid cooling, in particular water cooling or oil cooling, is provided. In the core, for this purpose, provision is generally made of cooling channels of the cooling system in the magnetically permeable body of the e.g. dynamo-electric machine.

DE 24 62 150 or EP 0 684 082 B1 discloses electromechanical transducers having corresponding cooling channels in a laminated section of the core. Electromechanical transducers having cooling facilities are furthermore also known from U.S. Pat. Nos. 3,675,056 A, 8,629,585 B2 and DE 10 2012 203 502 A1.

Conventional stators often exhibit nonuniform heat dissipation during operation. At winding overhangs of the winding system, for example, increased temperatures in comparison with the other components regularly arise. In addition, the rest of the temperature distribution as well is often inhomogeneous. This phenomenon is also generally caused by the fact that when the cooling medium flows through the cooling system, streaks of different temperatures are manifested and the through-flow of the cooling system takes place so nonuniformly that larger amounts of the cooling medium flow through certain regions of the cooling system and hence comparatively higher temperatures form in other regions of the cooling system with less through-flow (e.g. flow-related dead water zones). Thermal imbalance also arises since identical waste heat emission does not arise at all points of the stator.

This nonuniformity in the cooling system is passed on to the core as a nonuniform temperature distribution, and so material properties are depleted earlier in some regions of the core than in other regions, owing to the higher thermal loading.

US 2013/193786 A1 discloses an electromechanical transducer, comprising a stator having a lamination stack, wherein a plurality of axially extending, parallel cooling channels between windings are arranged in the lamination stack. An inflow to the cooling channels with a distribution is formed centrally with respect to the lamination stack in an axial direction, such that the cooling channels have through-flow from the inflow to outer ends. Each cooling channel has an opening at the outer ends, wherein the opening, in particular in relation to gravity, is adapted to the position of the respective cooling channel in the stator in such a way that a uniform through-flow is attained in all the cooling channels. What is disadvantageous about the electromechanical transducer known from US 2013/193786 A1 Is the complexity thereof.

US 2018/138784 A1, U.S. Pat. No. 9,419,499 B2 and CN 101 752 915 A furthermore disclose electromechanical transducers having cooling facilities in which nozzles for spraying and thus targeted cooling of winding overhangs are provided.

Taking the problems and disadvantages of the prior art as a departure point, the invention formulated the object of improving the heat dissipation from the core.

In order to achieve the object, the invention proposes a stator of the type defined in the introduction with the additional features of the characterizing part of the independent claim. Specifically, it is provided that the cooling system has at least one nozzle through which the cooling medium flows during operation, such that the cooling medium flows out as an accelerated jet downstream of the nozzle, wherein the nozzle is configured and oriented in such a way that a part of the winding system is struck by the accelerated jet from the nozzle, wherein the core has at least two bodies arranged axially next to one another, a first body and a second body, wherein the first body is arranged in a manner spaced apart from the second body by an axial gap, and wherein the cooling medium is combined in the axial gap from various flow paths guided in a parallel fashion.

The orientation of the nozzle is preferably such that the accelerated jet is directed at a winding overhang of the winding system at least in relation to the axial-radial orientation. In this case, the invention has recognized, inter alia, that for a balanced temperature distribution at the points with higher heat emission, more focused cooling must be effected. At the same time, besides targeted cooling of regions which have higher waste heat emission, the use of the nozzles according to the invention also enables a targeted distribution of the coolant in such a way that there is otherwise uniform cooling for a uniform temperature distribution.

The invention has furthermore advantageously recognized that by means of a combination in the axial gap between two bodies of the core, particularly expedient coolant guidance is made possible in which the coolant is guided inward from the axial ends of the core at which the winding overhangs are arranged. Accordingly, after being sprayed onto the winding overhangs at which the highest temperatures occur in the system, the coolant is guided away at the winding overhangs and guided along the windings through the stator. In particular, coolant guidance is thus provided in which the coolant in a regenerated state, i.e. at the lowest possible temperature, firstly strikes the winding overhangs and can dissipate the arising heat particularly efficiently there. Afterward, the remaining windings and the core are then subjected to through-flow and cooled in the process.

Unless indicated otherwise, in the present case terms such as radial, tangential, axial or circumferential direction relate to a longitudinal axis of the stator.

One aspect of the invention provides for the cooling system to provide a combination of flow paths guided parallel to one another, in particular all flow paths guided parallel to one another, downstream of the respective division. The divisions and combinations can be configured in each case in a cascaded fashion. The parallel guidance of flow paths enables more accurately targeted cooling of the individual heat-producing components. In principle, the term “parallel” used in this context is understood by the invention to mean not the geometric parallel arrangement, but rather only a division of an initially common flow into two flow paths and subsequent reunification or combination. This division and reunification or the parallel guidance can also be effected here in such a way that a flow path resulting from a division is split once again and downstream all are combined either simultaneously or successively.

A further aspect of the invention provides for the core to have a plurality of bodies and for the cooling system to provide for the flow of the cooling medium to be divided among the individual bodies and this division to be reunified afterward. A further division of the flow guidance can take place in the bodies themselves.

Preferably, the body or the bodies of the core is/are configured as lamination stacks.

For the separation of the two bodies by means of the axial gap, it can be expedient to provide spacers between the bodies, which prevent an axial approach vis-A-vis the bodies.

A good combination of cooling of the winding system and the cooling of the bodies of the core results if at least some winding sections extending axially through the core together with adjacent surfaces of the respective cutouts in the bodies define the channels having parallel throughflow in the cooling system in the body, such that the cooling medium flows along the respective winding section. In this case, the winding system can have insulation or main insulation between a conductor of the winding system and a wall of the cutout in which a winding section is arranged. A cooling channel or channel of the cooling system can expediently be provided between the main insulation and the wall. In this case, it is beneficial for the main insulation and/or the winding system itself or a winding section to have a depression at least partly forming the channel in the longitudinal direction of the channel, wherein the protuberance can be configured as an embossing in the insulation and/or the conductor material.

Preferably, the respective winding section is configured as part of a form-wound coil and is wound in such a way as to produce a basic form that already has portions of a cooling channel. As an alternative thereto and particularly preferably, a winding section is firstly produced as part of a form-wound coil without formation of a cooling channel and is subsequently provided with insulation or main insulation having at least one embossing, preferably introduced subsequently, such that the embossing together with a slot wall or cutout wall of the respective body produces a cooling channel portion. The embossing preferably has a longer extent in the axial direction than the cutout in which the winding section lies, such that an inflow and/or an outflow from the channel are/is formed at ends of the cutout. The winding section can consist of conductor bars and/or turns and/or partial conductors electrically connected in parallel.

Particularly expediently, the stator has a can in the region adjoining a rotor in the state ready for operation, said can—preferably hermetically—separating the stator from the rotor, such that the cooling system of the stator can be operated independently of the rotor or the cooling system of the stator is closed relative to the rotor.

In the case where the core is split into at least two bodies spaced apart axially from one another, it is expedient if the winding sections extend axially through the core—in a manner bridging the axial gap.

The axial gap can expediently be ensured by spacers.

One advantageous development of the invention provides that axially next to the core on a first side a first collecting space is provided upstream of the core for the cooling medium. Alternatively or additionally, axially next to the core on a second side a second collecting space can be provided upstream of the core for the cooling medium. In the case of the variant with two collecting spaces, spacing or division of the cooling medium flows in the cooling system upstream of the two collecting spaces is expedient. In other words, the cooling system then has a two-flow embodiment, wherein the two flow paths of the two flows each have a collecting space, from each of which particularly preferably there is division into mutually parallel flow guidances of the cooling medium preferably through in each case a different body of the core.

One advantageous development of the invention provides that the winding system has winding overhangs, wherein at least one winding overhang is at least partly arranged in a collecting space, wherein the at least one nozzle is oriented in such a way that the accelerated jet is directed at a winding overhang at least with regard to the axial-radial orientation. The orientation of the preferably plurality of nozzles can be purely radial or oblique with respect to the radial and axial direction. Particularly preferably, the nozzles are arranged radially on the outside with respect to the winding overhangs and the accelerated jet is directed at the at least one winding overhang parallel to the radial direction from the outside inward. In the case of a plurality of nozzles, these can be oriented and arranged in such a way that the individual jets, in relation to a respective jet central axis, define either substantially a radial plane in an imaginary ring-shaped connection to one another in the circumferential direction or a cone shape.

One advantageous development of the invention provides that the cooling system, in each case at the point leading into the collecting space, has an inlet channel which extends along the circumferential direction over at least one part of the circumference and which has outflow openings from the inlet channel into the collecting space. In this case, preferably, the outflow openings are configured in such a way that the cooling medium flows into the collecting space in a manner distributed uniformly over the circumference. Preferably, the inlet channel extends in each case over the entire circumference. All the outflow openings can be configured as nozzles in a wall of the inlet channel, in particular in such a way that the wall is configured as a perforated lamination. Alternatively, only some of the outflow openings are configured as nozzles, such that the other outflow openings preferably serve for distribution that is otherwise as uniform as possible.

The outflow openings can be provided at different circumferential positions and/or radial positions, and/or the outflow openings can at least partly be of different sizes and/or arranged with different spacings, and/or the outflow openings can preferably be configured in such a way that the circumferential distribution of the cooling medium through-flow among the outflow openings during rated operation substantially corresponds to a target circumferential distribution. The target circumferential distribution can preferably provide a uniform distribution over the circumference, such that no portions of the stator overheat. It is particularly preferred here if at least some of the outflow openings are configured as said nozzles into which the cooling medium flows and flows out in a manner directed at a part of the winding system as an accelerated jet.

One advantageous development of the invention provides that the cooling system is configured in such a way that upstream—of the collecting spaces arranged on both axial sides of the core—a first division into at least two flow paths guided parallel to one another is provided and the collecting spaces are situated in the flow paths guided in a parallel fashion.

Particularly if a high-quality cooling medium is used, it is expedient if the cooling medium is guided along a closed circuit. There is preferably a primary circuit of the cooling system, which primary circuit is configured in a closed fashion. Said primary circuit can be cooled from a different heat sink by means of a heat exchanger, e.g. by means of air cooling (secondary cooling).

Particularly advantageously, the cooling system is filled with the cooling medium in such a way that relative to the surroundings a reduced pressure of at least 0.1 bar, preferably 0.3 bar, prevails in the cooling system during operation. For this purpose, corresponding pressure regulation of the cooling system can be provided, which is configured in such a way that relative to the surroundings a reduced pressure of at least 0.1 bar, preferably 0.3 bar, prevails in the cooling system during operation. Preferably, the cooling system has a pump, which particularly preferably has a conveying pressure of at least Δp=0.3 bar, preferably between Δp=0.4 bar and 0.6 bar (e.g. Δp=0.5 bar). A reduced pressure in the stator has a positive effect on the stability of a can since the cylindrical shape of the can, in the case where an internal pressure is higher than the external pressure, is mechanically stabler than in the case of pressure relationships the other way round. Accordingly, it is possible for the can to be configured with a smaller wall thickness in the case of such a mode of operation, thus resulting in positive effects for the efficiency of the electromechanical transducer. During normal operation of the cooling system, it should be expected that a pressure difference of approximately 0.1 bar can be established in each case by way of the nozzles or outflow openings. The through-flow of the core along cooling channels provided there—in particular e.g. between the winding sections and the magnetically permeable bodies—can produce approximately a pressure difference of 0.3 bar.

Electromechanical transducers according to the invention are preferably used in the constructional form of a generator for wind power installations, since they have a high power density in conjunction with a compact design.

One preferred field of application of the invention is therefore generators, in particular having permanent magnet rotors, in particular of wind power installations, such that the invention also relates to generators or to generators of wind power installations or to a wind power installation having a generator comprising a stator according to the invention. Another field of application of the invention is asynchronous machines, in particular squirrel-cage motors. In the case of asynchronous machines, the can must be embodied in a relatively thin-walled fashion on account of the smaller air gaps in comparison with the permanent magnet rotors.

In this case or in addition, a computer-implemented method for simulating the operation of a stator according to the invention can be used. In particular, it is expedient if the design of a stator or of a corresponding overall machine (electromechanical transducer) Is simulated by means of the computer-implemented method. In this way, it is possible to find out the best possible configuration of variable design parameters and operating parameters taking account of the temperature distribution in the core that arises during the simulation under different operating conditions. Furthermore, the possibility of the simulation is also valuable for being able, concomitantly during operation, to make statements about the temperature distribution and possible instances of limit values being exceeded or instances of material damage and optionally for deciding which operation scenario ought actually to be implemented. Simulation can provide assistance concomitantly during operation in regard to defining maintenance intervals, making service life predictions and providing spare parts. In this context, if there is a link to a sensor between the simulation—i.e. the virtual image representation of the stator—and the physical embodiment, at the present time the term digital twin is also often used in the jargon.

Accordingly, the invention also relates to a computer program product for carrying out a method for simulation by means of at least one computer. In this case, it is particularly preferred if there is a link to at least one sensor between the virtual image representation of the stator and the physical embodiment, such that the simulation is synchronizable with the physical embodiment.

One advantageous configuration of the invention is explained in greater detail below on the basis of an exemplary embodiment illustrated in principle. It is shown in:

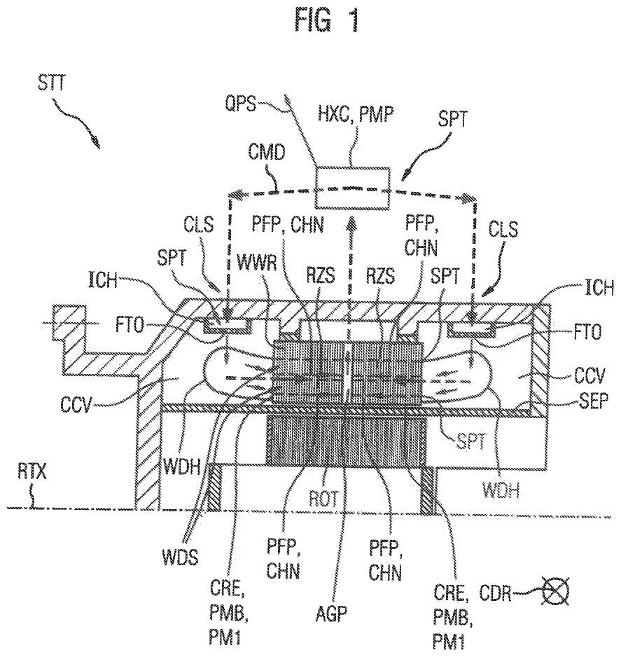

FIG. 1 a schematic illustration of an electromechanical transducer in a radially halved longitudinal sectional view encompassing details of the cooling system,

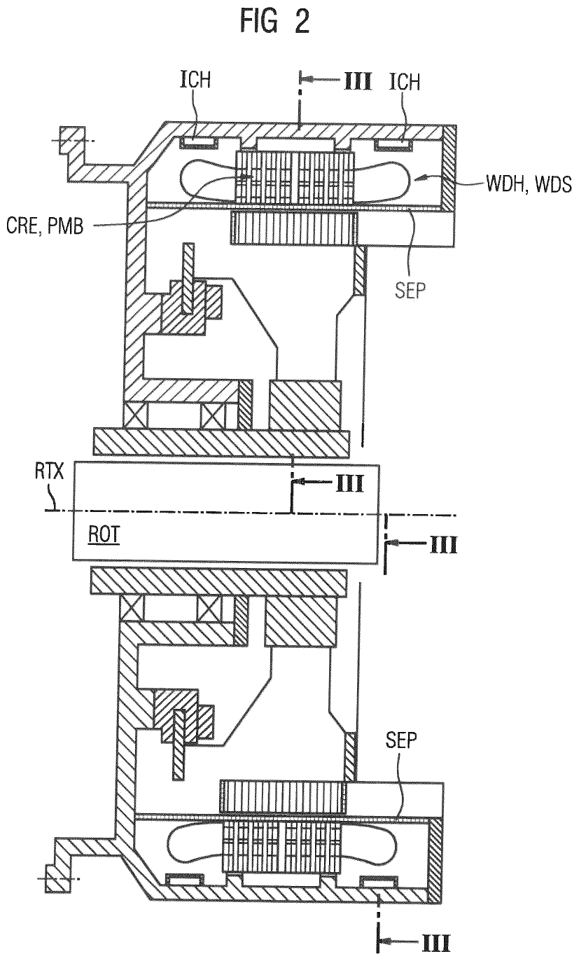

FIG. 2 a schematic illustration of an electromechanical transducer in a longitudinal sectional view,

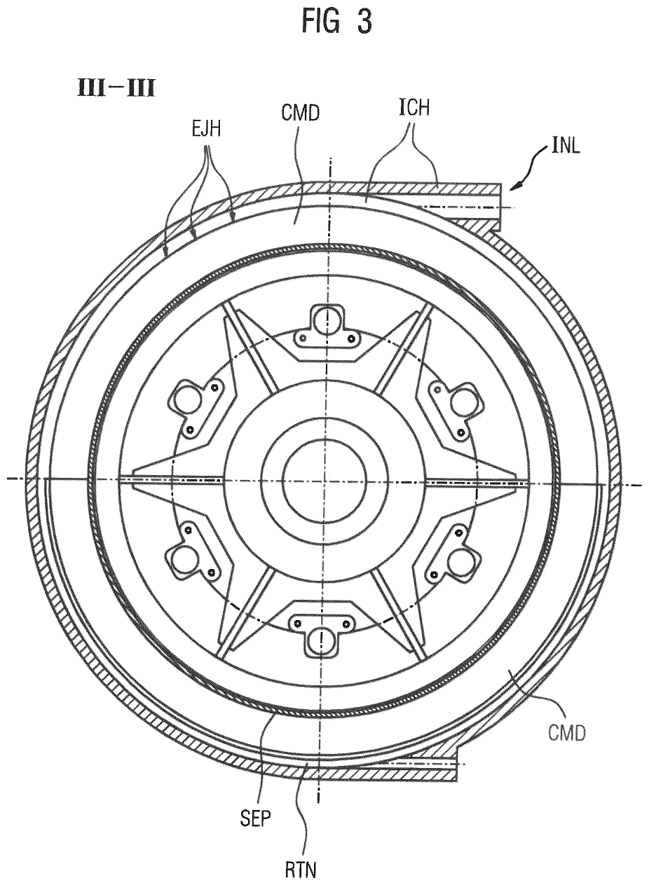

FIG. 3 the section III-III identified in FIG. 2,

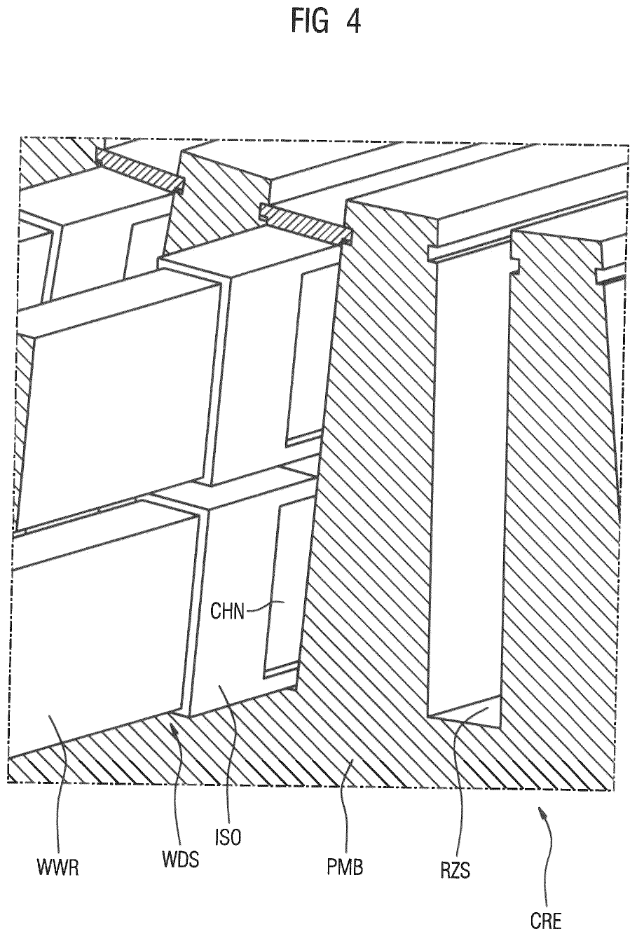

FIG. 4 a perspectively schematic detail view of winding sections in slots of the body,

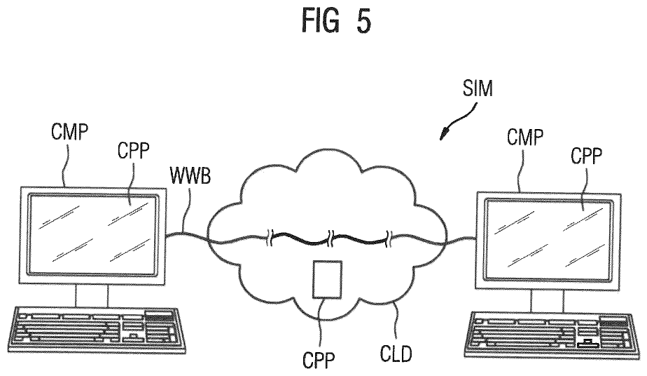

FIG. 5 a schematic illustration of a computer-executed simulation of an arrangement/a method according to the invention, computer program product.

FIG. 1 shows a radially halved schematic longitudinal sectional illustration of an electromechanical transducer embodied as a dynamo-electric machine—here a generator —, with the main emphasis of the illustration being on a stator STT, which surrounds a rotor ROT substantially cylindrically in the circumferential direction CDR and along a longitudinal direction of a longitudinal axis RTX. FIG. 2 likewise shows—here in a whole radial illustration—a longitudinal sectional view. FIG. 3 shows the section III-III identified in FIG. 2.

The rotor ROT mounted rotatably about the longitudinal axis RTX is merely suggested in the illustration. The stator STT configured for interaction with the rotor ROT comprises a cooling system CLS, a winding system WDS and a core CRE.

A cooling medium CMD flows through the cooling system CLS. In this case, proceeding from a heat exchanger HXC, the cooling system CLS extends firstly proceeding from a first division SPT of the cooling medium CMD in two flows each to an axial end of the stator STT, where the cooling medium CMD at the axial ends of the stator STT in each case enters a collecting space CCV.

The two bodies PMB of the core CRE have channels CHN arranged in the longitudinal direction along the winding sections WWR. The cooling medium CMD accordingly flows through the bodies PMB in an axial direction at least in portions. Downstream of the through-flow of the two bodies PMB, the two flow paths PFP guided in a parallel fashion are recombined.

The winding system WDS comprises an insulation ISO. The core CRE comprises two magnetically permeable bodies PMB, a first body PM1 and a second body PM2, which are spaced apart axially from one another. An axial gap AGP is situated between the two bodies PM1, PM2. Winding sections WWR of the winding system WDS are at least partly arranged in cutouts RZS of the core CRE (more specific details about this can also be gathered from FIG. 3). The winding sections WWR extend through the bodies PMB of the core CRE in a manner bridging the axial gap AGP.

The parallel flow paths PFP of the cooling medium CMD are combined in the axial gap AGP, wherein downstream of the axial gap AGP the cooling medium CMD is fed to the heat exchanger HXC again. The heat exchanger HXC feeds the dissipation loss OPS to a heat sink (not illustrated). The latter can be a secondary air cooling facility, for example. In addition, the heat exchanger HXC also comprises suitable means for conveying the cooling medium CMD in a closed circuit (a pump is generally used here since the cooling medium CMD is used in the liquid phase given the capacities requiring heat dissipation that are to be dealt with)—unless a sufficient natural circulation is ensured. In the present case, a pump PMP having a conveying pressure of at least 0.3 bar, preferably between 0.4 bar-0.6 bar (e.g. Δp=0.5 bar), is integrated in the heat exchanger HXC. The cooling system CLS is filled with the cooling medium in such a way that relative to the surroundings a reduced pressure of approximately 0.3 bar prevails in the cooling system during operation. For this purpose, corresponding pressure regulation (in the present case part of the heat exchanger HXC) of the cooling system CLS can be provided, which is configured in such a way that relative to the surroundings a reduced pressure of at least 0.1 bar, preferably 0.3 bar, prevails in the cooling system during operation. The reduced pressure in the stator relative to atmospheric pressure has a positive effect on the stability of the can SEP since the cylindrical shape of the can SEP in the case where an internal pressure is higher than the external pressure is mechanically stabler.

The cooling system CLS has nozzles FTO through which the cooling medium CMD flows during operation, such that the cooling medium CMD flows out as an accelerated jet downstream of the nozzle FTO. In the present case, said nozzles FTO are configured as outflow openings EJH from an inlet channel ICH into the collecting space CCV on both axial sides. The inlet channel ICH extends in each case along the circumferential direction CDR on an inner side of a radial outer wall of the collecting space CCV situated on the two axial sides. In this case, the outflow openings EJH are formed in a wall of the inlet channel ICH, in particular in such a way that the wall is configured as a perforated lamination. This arrangement ensures that the cooling medium CMD flows into the collecting space in a manner distributed uniformly over the circumference. The outflow openings EJH are configured as said nozzles FTO into which the cooling medium CMD flows and flows out in a manner directed at the winding overhangs WDH as an accelerated jet.

All the flow paths PFP guided in a parallel fashion are unified in the axial gap AGP.

The cross section III-III shown in FIG. 3 has an offset in the center and shows both the feed INL of the cooling medium CMD via the inlet channel ICH through the outflow openings EJH into the collecting space CCV and also (in the lower region of the illustration) the return RTN of the cooling medium CMD to the heat exchanger HXC.

FIG. 4 shows a perspectively schematic detail view of winding sections WWR arranged in cutouts RZS configured as slots in the body PMB. The winding sections WWR are provided with an insulation ISO, wherein channels CHN running substantially parallel to one another for through-flow by means of the cooling medium CMD of the cooling system CRS are provided as embossings in the insulation ISO. In this way, the channels CHN run in an axial longitudinal direction along the winding sections WWR and along a surface of the bodies PMB, thereby ensuring uniform heat dissipation from the core CRE. The cooling medium CMD cools both the bodies PMB and the individual winding sections WWR by virtue of the fact that the winding sections WWR extending axially through the core CRE together with adjacent surfaces of the respective cutouts RZS in the bodies PMB define the channels CHN with parallel through-flow in the cooling system in the body PMB, such that the cooling medium CMD flows at the respective winding section WWR and along the bodies PMB.

In the collecting spaces arranged upstream of the respective through-flow of the bodies PMB, as viewed proceeding from the cooling system CLS, the first division provided in the heat exchanger HXC in the example is followed by a second division SPT of the cooling medium CMD into parallel flow paths through the respective bodies PM1, PM2. Accordingly, the division into parallel flow paths PFP is virtually cascaded, such that after a first division SPT the collecting spaces CCV are situated in flow paths PFP guided in a parallel fashion and a second division SPT into flow paths PFP guided parallel to one another along the channels CHN into the body PMB takes place in the collecting spaces CCV.

FIG. 5 shows a schematic illustration of a simulation SIM of an arrangement/a method according to the invention, said simulation being executed on a computer CMP—here on a plurality of computers CMP of a network WWB comprising a cloud CLD. The software installed on the computers CMP is a computer program product CPP which, when executed on at least one computer CMP, enables the user, by means of the interfaces screen and keyboard, to have an influence or carry out configuration and gain knowledge on the basis of the executed simulation SIM, such that in particular technical design decisions can be assisted and verified by means of the simulation.

Although the invention has been more specifically illustrated and described in detail by means of the preferred exemplary embodiment, the invention is not restricted by the examples disclosed. Variations thereof can be derived by a person skilled in the art, without departing from the scope of protection of the invention such as is defined by the patent claims hereinafter.

1.-14. (canceled)

15. A stator of an electromechanical transducer, in particular of a dynamo-electric machine, configured for interaction with a rotor, the stator extending along a longitudinal axis and comprising:
a winding system comprising winding overhangs;
a cooling system designed for through-flow of a cooling medium and comprising a nozzle through which the cooling medium flows during operation, such that the cooling medium flows out as an accelerated jet downstream of the nozzle, said nozzle designed and oriented and directed at a respective one of the winding overhangs of the winding system in such a way that a part of the winding system is struck by the accelerated jet from the nozzle; and
a core comprising a magnetically permeable body designed to include at least a first body and a second body which are arranged axially next to one another, with the first body being arranged in spaced-apart relationship from the second body to define an axial gap there between, said core including cutouts for at least partial arrangement of winding sections of the winding system,
wherein the cooling medium is combined in the axial gap from various flow paths guided in a parallel fashion, and
wherein the cooling medium is guided away at the winding overhangs and guided along the windings sections through the cutouts.

16. The stator of claim 15, wherein the cooling system is designed in such a way that the cooling medium is guided along a closed circuit.

17. The stator of claim 15, wherein axially next to the core on a first side a first collecting space is provided upstream of the core for the cooling medium, and/or wherein axially next to the core on a second side a second collecting space is provided upstream of the core for the cooling medium.

18. The stator of claim 17, wherein at least one of the winding overhangs being is at least partly arranged in one of the first and second collecting spaces, said nozzle being oriented in such a way that the accelerated jet is directed at the respective one of the winding overhangs at least with regard to an axial-radial orientation.

19. The stator of claim 18, wherein the cooling system comprises a further said nozzle, said first and second collecting spaces arranged in such a way that upstream of the first and second collecting spaces a first division into at least two flow paths of the cooling medium, which are guided parallel to one another, is provided, with the first and second collecting spaces and the nozzles directed at winding overhangs being situated in the flow paths guided in a parallel fashion.

20. The stator of claim 17, wherein the cooling system at a point leading into the first and second collecting spaces comprises an inlet channel which extends along a circumferential direction over at least one part of a circumference and which includes outflow openings from the inlet channel into the first and second collecting spaces, with the outflow openings designed in such a way that the cooling medium flows into the first and second collecting spaces in a manner distributed uniformly over the circumference.

21. The stator of claim 20, wherein at least some of the outflow openings are designed as the nozzles into which the cooling medium flows and flows out in a manner directed at a part of the winding system as accelerated jet.

22. The stator of claim 20, wherein the inlet channel is designed to extend over the entire circumference.

23. The stator of claim 20, wherein the outflow openings are designed as nozzles in a wall of the inlet channel.

24. The stator of claim 23, wherein the wall is configured as a perforated lamination.

25. The stator of claim 15, wherein the cooling system comprises channels arranged in the body of the core and configured in such a way that the cooling medium flows through the body in at least in one portion in an axial direction, said cooling system designed to divide the cooling medium between at least two flow paths guided parallel to one another along the core.

26. The stator of claim 25, wherein at least some of the winding sections of the winding system extend axially through the core together with adjacent surfaces of the cutouts so as to define the channels having parallel throughflow in the cooling system in the body, such that the cooling medium flows along the respective winding sections.

27. The stator of claim 15, wherein the cooling system is filled with the cooling medium in such a way that relative to a surroundings a reduced pressure of at least 0.1 bar prevails in the cooling system during operation.

28. The stator of claim 15, wherein the cooling system is filled with the cooling medium in such a way that relative to a surroundings a reduced pressure of at least 0.3 bar prevails in the cooling system during operation.

29.-30. (canceled)
